(19) United States
(12) Patent Application Publication
(10) Pub. No.: US 2023/0092998 A1
(43) Pub. Date: Mar. 23, 2023

(54) METHOD FOR MANUFACTURING A MEMORY RESISTOR DEVICE

(71) Applicant: UCL Business Ltd., London (GB)

(72) Inventors: Longfei Zhao, London (GB); Anthony Kenyon, London (GB); Adnan Mehonic, London (GB); Wing Ng, London (GB)

(21) Appl. No.: 17/933,788

(22) Filed: Sep. 20, 2022

(30) Foreign Application Priority Data
Sep. 21, 2021 (GB) 2113456.4

(51) Int. Cl. H01L 45/00

(52) U.S. Cl. CPC H01L 45/165; H01L 45/08; H01L 45/145; H01L 45/1616

(57) ABSTRACT

Methods for manufacturing memory resistor devices and memory resistor devices manufactured according to such methods. A method includes depositing a first layer of dielectric material onto a substrate comprising a first electrode; bombarding the deposited first layer with an ion beam to create one or more defects in the first layer; depositing a second electrode such that the deposited first layer is between the first electrode and the second electrode; electroforming the first layer by applying an electroforming voltage between the first electrode and the second electrode.

This application claims the benefit of United Kingdom Patent Application No. 2113456.4, filed Sep. 21, 2021. The entire contents of United Kingdom Patent Application No. 2113456.4 are incorporated herein by reference.

### TECHNICAL FIELD

The invention relates primarily, but not exclusively, to memory resistor devices and methods of manufacturing memory resistor devices.

### BACKGROUND

Memory resistor devices are devices which include multiple conductive states in which a resistance across the device (i.e., between electrodes of the device) is different for each state. Memory resistors further have the ability to maintain, or remember, their last resistance state even when there is no bias voltage applied. Consequently, memory resistors have found uses as non-volatile memory devices, sometimes referred to as resistive random-access memory (ReRAM or RRAM).

Some memory resistor devices are manufactured using dielectric materials which facilitate the formation of conductive filaments between electrodes. The formation of the conductive filaments allows the memory resistor device to achieve multiple conductive states as the conductive filaments can be created or destroyed through the application of a particular voltage bias.

The conductive filaments can form due to inhomogeneities in the dielectric material included in the memory resistor device. Inhomogeneities of the dielectric material can be created in a number of different ways. For example, the dielectric material can be deposited using sputtering techniques, as these typically result in columnar growth of the dielectric material. Alternatively, providing a rough or textured electrode surface can similarly promote columnar growth of the dielectric material.

There is a desire for improved methods of manufacturing memory resistor devices.

### SUMMARY

Aspects of the invention are set out in the accompanying claims.

According to a first aspect, there is provided a method for manufacturing a memory resistor device, the method comprising: depositing a first layer of dielectric material onto a substrate comprising a first electrode, wherein the deposited first layer is electrically insulating; bombarding the deposited first layer with an ion beam to create one or more defects in the first layer; depositing a second electrode such that the deposited first layer is between the first electrode and the second electrode; electroforming the first layer by applying an electroforming voltage between the first electrode and the second electrode.

Accordingly, a method is provided whereby a memory resistor device can be manufactured in a manner which allows for fine control of the electrical properties of the device and greater consistency between devices. In particular, the resistive switching (otherwise known as resistance switching) capability of the device is induced by the bombardment of the dielectric layer with an ion beam. As such, the resistive switching properties (e.g., switching voltage) of the device are determined primarily by the ion bombardment, a process which can be finely controlled (e.g., ion dosage and bombardment energy). Consequently, devices manufactured according to this method have resistive switching properties which can be effectively predicted in advance (e.g., a given ion bombardment regime will result in a device with particular properties) and are more consistent across multiple devices.

In a particular embodiment, prior to the bombarding the deposited first layer is electrically inert. In other words, the dielectric layer is not capable of exhibiting resistive switching. As such, without the subsequent ion bombardment step of the first aspect, the resultant device would not electroform and therefore would not resistively switch.

In this embodiment, the electroforming voltage of the bombarded device may have an absolute value of up to 20V, more preferably up to 15V. Accordingly, despite the dielectric layer being electrically inert prior to the ion bombardment step, the final device is able to electroform at a voltage comparable to memory resistor devices manufactured according to existing methods.

Advantageously in some embodiments, the one or more defects in the first layer comprise one or more structural defects in the first layer. In other words, the chemical composition of the dielectric layer is unchanged by the ion bombardment, providing consistency in the electrical properties. In this embodiment, the one or more defects in the first layer may comprise one or more oxygen vacancies, in particular if the insulating layer is an oxide material.

In some embodiments, the first layer is formed of silicon oxide, SiOx. Accordingly, a memory resistor device manufactured according to this method may be readily incorporated into a resistive random-access memory (ReRAM) device.

According to some embodiments, the ion beam comprises ions of a noble gas. As such, the inert nature of noble gases promotes structural, rather than chemical, defects in the dielectric layer, thereby promoting the formation of conductive filaments in the dielectric layer (and therefore resistive switching properties). Advantageously in this embodiment, the ion beam comprises argon ions. The relatively large mass of argon ions increases the likelihood of structural defects being created within the dielectric layer.

In some embodiments, the bombarding comprises providing a masking material on a portion of a surface of the first layer to be bombarded to control a location of the one or more defects in the first layer. In this manner, the location and number of the defects, and hence the conductive filaments, within the dielectric layer may be more finely controlled, thereby providing more predictable electrical properties in the resultant device. Advantageously in this embodiment, the masking material may be arranged to prevent ions of the ion beam from impacting the first layer, and wherein the masking material comprises one or more cavities permitting ions of the ion beam to pass therethrough. As such, it is straightforward to choose the number, location and size of the cavities in the material and therefore the defects may be distributed throughout the dielectric material.

In some embodiments, the bombarding comprises controlling an energy of the ion beam to adjust a distance between the one or more defects and the substrate and/or a surface of the first layer to be bombarded. In other words, the energy of the ion beam may be controlled to locate the defects closer to a particular electrode of the device. As such, the electrical properties of the device can be further controlled by the ion bombardment process.

Advantageously in this embodiment, the energy of the ion beam may be configurable to a first energy to cause the one or more defects to be closer to the substrate than to the surface of the first layer to be bombarded and/or wherein the energy of the ion beam may be configurable to a second energy to cause the one or more defects to be closer to the surface of the first layer to be bombarded substrate than to the substrate. As such, the electrical properties of the substrate or second electrode, and hence the device, may be controlled by the ion bombardment process.

In some embodiments, the bombarding comprises providing a charge dissipation layer on a portion of a surface of the first layer to be bombarded, wherein the charge dissipation layer is electrically grounded and comprises one or more cavities to allow ions of the ion beam to pass therethrough. As such, the accumulation of charge within the device may be prevented, thereby ensuring that the ion dosage of the dielectric layer may be more accurately determined. Advantageously, the charge dissipation layer may comprise molybdenum.

In some embodiments, the first layer is deposited using atomic layer deposition, ALD. As such, deposition methods which generally produce uniform layers of dielectric material which are largely defect-free (and therefore incapable of being electroformed) may be used, while still providing a device which is capable of resistively switching.

According to a second aspect, there is provided a memory resistor device manufactured according to the method of any of the examples described above.

In some embodiments, the first layer includes one or conductive filaments which extend at least partially between the first electrode and the second electrode. In this manner, the memory resistor device is in a comparatively low resistance state. Upon the application of a first particular voltage, the one or conductive filaments may be at least partly destroyed, thereby causing the device to enter a comparatively high resistance state. The one or more conductive filaments may be reformed upon the application of a second particular voltage. In this manner, the device is capable of operating as a memory resistor device.

### BRIEF DESCRIPTION OF DRAWINGS

Embodiments of the invention will now be described, by way of example only, with reference to the following figures.

In accordance with one (or more) embodiments of the present invention the Figures show the following:

FIG. 1 illustrates a first step of an example method for manufacturing a memory resistor device.

FIG. 2 illustrates a second step of the example method for manufacturing a memory resistor device.

FIG. 3 illustrates a device after the second step of the example method for manufacturing a memory resistor device.

FIG. 4 illustrates a third step of an example method for manufacturing a memory resistor device.

FIG. 5 illustrates a current-voltage graph for an electroforming process of a fourth step of an example method for manufacturing a memory resistor device.

FIG. 6 illustrates a memory resistor device manufactured according to the example method for manufacturing a memory resistor device.

FIG. 7 illustrates a set of current-voltage curves for a memory resistor device manufactured according to the example method for manufacturing a memory resistor device.

FIG. 8 illustrates a flowchart outlining a method for manufacturing a memory resistor device.

Any reference to prior art documents in this specification is not to be considered an admission that such prior art is widely known or forms part of the common general knowledge in the field.

As used in this specification, the words “comprises”, “comprising”, and similar words, are not to be interpreted in an exclusive or exhaustive sense. In other words, they are intended to mean “including, but not limited to”.

The invention is further described with reference to the examples below. It will be appreciated that the invention as claimed is not intended to be limited in any way by these examples. It will be further recognised that the skilled reader will understand from the teaching herein that integers and features of different embodiments may be used in any suitable and advantageous combination.

### DETAILED DESCRIPTION

Some comparative methods of manufacturing memory resistor devices involve promoting the formation of conductive pathways (or filaments) in a dielectric material between two electrodes, where the conductive filaments form in the presence of a voltage bias. The formation of conductive pathways between electrodes lowers the resistance of the memory resistor device. Furthermore, the conductive pathways are not destroyed once the voltage bias has been removed and as such the memory resistor device is maintained in the same resistance state once the voltage bias has been removed.

The conductive pathways generally form at defects in the dielectric material and can include, for example, particles or clusters of semiconductor material within the dielectric layer, or oxygen vacancies in the dielectric material (for example for oxide-based dielectric materials). Existing methods for producing memory resistor devices involve providing a dielectric material including such defects via any of a number of deposition mechanisms (i.e. any defects in the dielectric material are introduced when the dielectric material is deposited). However, these approaches do not produce memory resistor devices with consistent electrical properties.

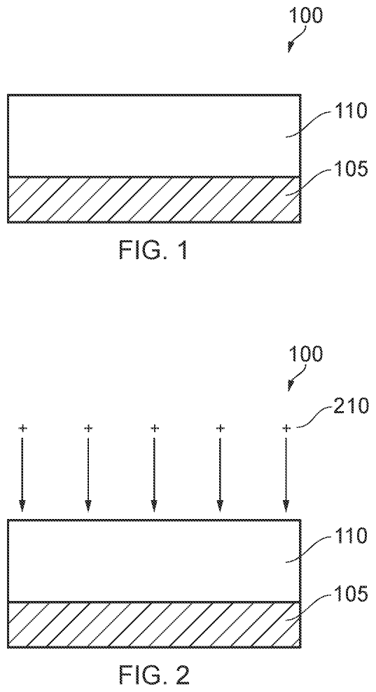

FIGS. 1-6 show steps in an example method for manufacturing a memory resistor device 100 where the variability in electrical properties between multiple devices 100 manufactured according to this method is reduced. In particular, the electrical properties (e.g., switching voltage) of the memory resistor device 100 are more predictable and more consistent across multiple devices.

FIG. 1 shows a first step of the example method. In this step, a first layer 110 of a dielectric material is deposited onto an electrode 105. The dielectric material could, for example, be silicon oxide (SiOx) or any other dielectric material suitable for use in memory resistor devices, such as silicon nitride, silicon carbide or silicon oxynitride, however non-silicon-based materials may also be used, such as oxides of hafnium, tantalum, titanium, zinc, aluminium, niobium, or others.

The dielectric material is amorphous and so generally includes no microstructure and few structural defects. The dielectric material may also be thought of as being homogenous or uniform above the nanometre scale. In contrast, dielectric layers deposited as part of existing memory resistor manufacturing methods generally include dielectric layers which are inhomogeneous above the nanometre scale and include structural defects which promote resistive switching. The dielectric material according to the present example may thus be deposited, for example, using atomic layer deposition (ALD), which typically produces a uniform amorphous layer of the dielectric material, however other techniques, such as chemical vapour deposition (CVD), may also be used. The dielectric layer may be, for example, less than 50 nm in thickness, for example less than 30 nm, less than, 20 nm, less than 10 nm, or less than 5 nm.

The dielectric material deposited on the electrode 105 is not capable of exhibiting resistive switching. In particular, the number of defects in the deposited dielectric material is too small to allow the formation of conductive pathways within the dielectric material. Specifically, the number of defects in the deposited dielectric material is too small to allow the formation of conductive pathways within the dielectric material without causing destructive breakdown of the device (for example under a large electric field). In other words, the dielectric material deposited on the electrode 105 is electrically inert.

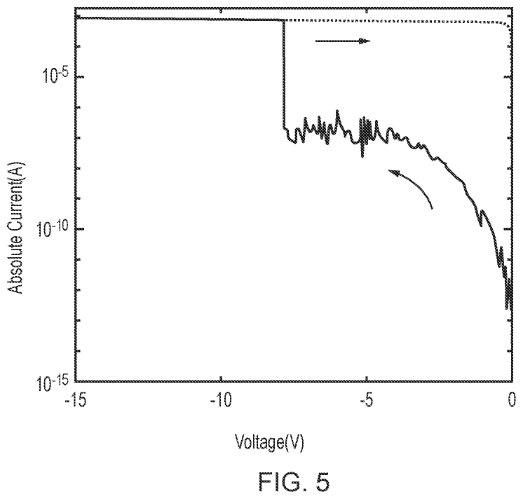

Resistive switching is typically initially induced in a memory resistor device by an electroforming process, as discussed in relation in to FIG. 5. Such an electroforming process can include applying a pulsed electroforming voltage across the memory resistor device. Alternatively, the electroforming process may include gradually increasing an absolute voltage applied across the dielectric material until the electroforming voltage is reached. The absolute value of the electroforming voltage may in some cases be up to 2V, up to 3V, up to 5V, up to 10V, up to 15V, or up to 20V for typical resistive memory devices. However, after the first step of the example method (the deposition of the dielectric material but before the second step of the example method discussed in relation to FIG. 2) the first layer 110 of a dielectric material is amorphous and thus includes a small number of defects. As such, in order for the first layer 110 to electroform a large voltage (e.g., approximately 40V) may be required in order to induce resistive switching (or it may not be possible to induce resistive switching at all). However, such large voltages can result in large currents and heating of the device 100, thereby causing damage to the first layer 110 or other components of the device 100. In this manner, the first layer 110 of can be regarded as unable to electroform and unable to resistively switch.

The electrode 105 may be formed of molybdenum or any other suitable material, such as silicon (polycrystalline or crystalline), indium tin oxide (ITO), titanium nitride (TiN), graphene, zinc oxide, tin oxide, and metals such as gold, silver, copper, titanium, tungsten, aluminium, platinum and chromium, however this is not an exhaustive list. Furthermore, the dielectric layer may be deposited directly onto the surface of the electrode 105, or one or more intermediate layers, such as a wetting layer, could be deposited before the dielectric layer. In this manner, the dielectric material may be deposited onto a substrate which includes the electrode 105 but that may also include one or more additional layers.

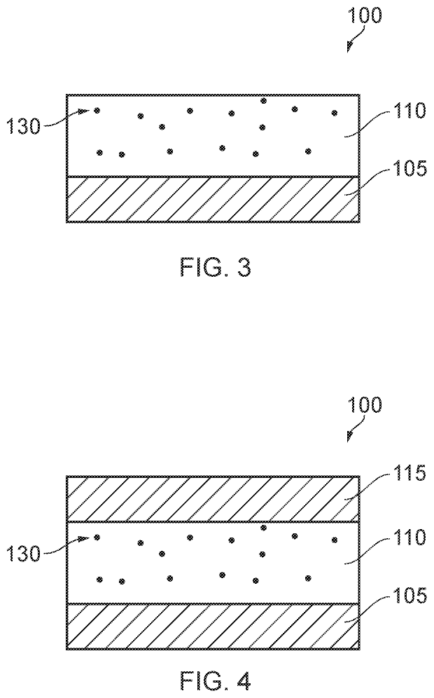

FIG. 2 shows a second step of the example method. In this step, the first layer 110 of dielectric material is bombarded with ions 210. For example, the first layer 110 may be bombarded with an ion beam. The bombardment of the first layer 110 creates defects in the bulk of the dielectric material which can form the basis of conductive pathways in the dielectric material. FIG. 3 shows the device 110 after the ion bombardment step of FIG. 2, where the dielectric material includes defects 130.

The defects 130 are physical defects caused by the ions 210. In particular, the composition and energy of the ions 210 is chosen to avoid chemical change in the dielectric material. In other words, the ion bombardment does not alter the stoichiometry of the first layer 110. The ions 210 used in the bombardment may be ions of a noble gas, due to the inert nature of noble gases. For example, the ions 210 may be argon ions, due to the comparatively large mass of argon ions, however other noble gases such as krypton and xenon could alternatively be used, as this can increase the likelihood of creating defects in the bulk of the dielectric material. In examples where the dielectric material is SiOx or another oxide material, the defects may be oxygen vacancies.

The location of the defects induced by the ion bombardment may be controlled by controlling the location at which the ions impact the first layer 110. For example, a masking layer (not shown) containing one or more cavities may be applied to the first layer 110 prior to commencing the ion bombardment. Standard lithography techniques understood by the person skilled in the art may be used to create the cavities in the masking layer. The masking material may absorb ions incident on itself, but may allow ion to pass through the cavities. Accordingly, the location of the defects may be determined by the location of the cavities in the masking material.

In some examples, the masking layer may also act as a charge dissipation layer. In particular, the masking material may be formed of an electrically conductive material that is electrically grounded. As an example, the charge dissipation layer (or masking layer) may be formed of molybdenum, however other materials capable of absorbing ions incident thereon may be used. In this manner, ions incident on the charge dissipation layer may be absorbed by the charge dissipation layer, however due to the grounding of the charge dissipation layer, the accumulation of charge in the first layer 110 and/or in the masking layer (charge dissipation layer) is prevented. Accordingly, it is possible to more accurately determine the ion dose received by the first layer 110, as the ions 210 are not deflected away from the first layer 110 due to the build-up of charge therein. As such, it is possible to more accurately predict the distribution of defects in the first layer 110 and therefore predict the electrical properties of the device 110, including the switching voltage. Consequently, memory resistor devices can be more reliably and consistently produced with particular desired properties.

In the present example, the defects 130 are shown as being distributed randomly throughout the first layer 110, however the distribution of the defects 130 may be more finely controlled in order to alter the properties of the device 100. For example, the depth of the defects 130 within the first layer 110 may be controlled, for example by adjusting the energy of the ion beam. In this manner, the defects may be more highly concentrated closer to the first electrode 105 or the second electrode 115, based on the desired properties of the device. In an example, where the defects 130 are oxygen vacancies, the oxygen vacancies 130 may be concentrated closer to a particular electrode which may alter the oxidation state of the electrode, thereby altering the properties of the electrode, and the device as a whole.

FIG. 4 shows a third step of the example method. In this step, a second electrode 115 is provided on the device. For example, the electrode 115 may be deposited using sputtering or evaporation techniques, however other means of providing the electrode 115 may be used. The second electrode 115 may, for example, be formed of gold, however other materials such as silicon (polycrystalline or crystalline), indium tin oxide (ITO), titanium nitride (TiN), graphene, tin oxide, and metals such as, silver, copper, titanium, tungsten, molybdenum, aluminium, platinum and chromium may be used.

The electrode 115 may, for example, be more than 100 nm in thickness, or may alternatively be less than 100 nm in thickness. Furthermore, a wetting layer (for example of titanium) which may be less than 5 nm thick may be deposited before the electrode 115 to improve adhesion of the electrode to the device 100. The shape of the electrode 115 may be defined using photo- or electron beam lithography and wet (chemical) or dry (plasma) etching, as appropriate. Other electrode 115 structures and materials may be used according to the desired application.

FIG. 5 shows a fourth step of the example method. FIG. 5 depicts a current-voltage (I-V) curve for an electroforming process for the device 110 shown in FIG. 4. A voltage is applied between the first electrode 105 and the second electrode 115. The voltage may be a voltage pulse at an electroforming voltage. Alternatively, the absolute value of the voltage may be gradually increased (a voltage sweep) until the electroforming voltage is achieved. During this process, the absolute current passing through the device 100 sharply increases (as shown in the I-V curve at approximately 8V), indicating that the device 100 has electroformed and entered a low-resistance state. The absolute value of the voltage may be decreased to zero. The absolute value of the voltage may be up to approximately 2V, up to approximately 3V, up to approximately 5V, up to approximately 10V, up to approximately 15V, or up to approximately 20V20V, or up to approximately 15V.

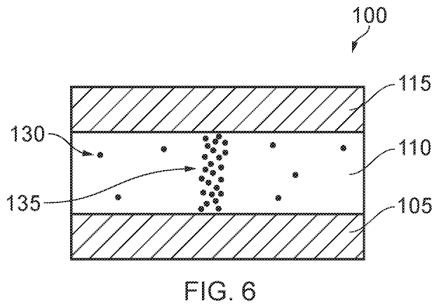

As shown in FIG. 6, the electroforming process shown in FIG. 5 causes the formation of one or more conductive filaments 135 in the first layer 110 extending at least partially between the first electrode 105 and the second electrode 115. In other words, the device 100 has entered a low-resistance state as a result of the electroforming process. In examples where the defects 130 generated during the ion bombardment process of FIG. 2 are oxygen vacancies, the conductive filament 135 is formed of these oxygen vacancies. This conductive filament 135 provides a conductive pathway between the first electrode 105 and the second electrode 115, thereby lowering the resistance of the device.

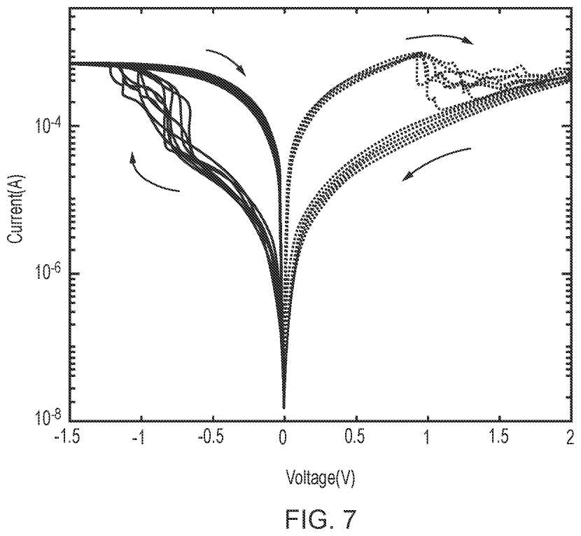

The device 100 is then capable of operating as a memory resistor device. As shown in FIG. 7, which depicts a set of I-V curves covering several cycles for the device 100 after the electroforming process of FIG. 5, the device 100 exhibits I-V hysteresis as the device 100 includes a low-resistance state (shown by comparatively higher current) in which the conductive filament(s) 135 is(are) present, and a high-resistance state (shown by comparatively lower current) in which the conductive filament(s) 135 is(are) not present. For example, starting at 0V in the high-resistance state, the magnitude of the voltage may be increased (for example to a voltage value of −1.5V) during which time the voltage induces the formation of a conductive filament(s) 135 and the device enters the low resistance state. The magnitude of the voltage can then be decreased (for example to zero), during which process the device remains in the low-resistance state, where comparatively higher current passes through the device 100.

Starting again from 0V, where the device 100 remains in the low-resistance state, the voltage can then be increased (for example to approximately 1.5V to 2V). During this voltage increase, the device 100 transitions to the high-resistance state (shown by a drop in current passing through the device). When the voltage is then decreased to 0V, the device 100 remains in the high-resistance state (with comparatively lower current than when the positive voltage was previously increased with the device in the low-resistance state). In other words, when the device enters the low-resistance state via the application of a particular voltage, the device remains in the low-resistance state until As such, the device 100 is operable as a memory resistor device. This is just one method of operating the memory resistor device 100 and the person skilled in the art would appreciate that a variety of other methods of operating the memory resistor device may be used.

While the electroforming process described above may be used to induce resistive switching properties in devices that have been subject to ion bombardment (as discussed in relation to FIG. 2), this electroforming process may not always be required. In particular, if the quantity of ion bombardment (i.e., the dosage) is sufficiently high, devices described herein may exhibit resistive switching without requiring an electroforming process.

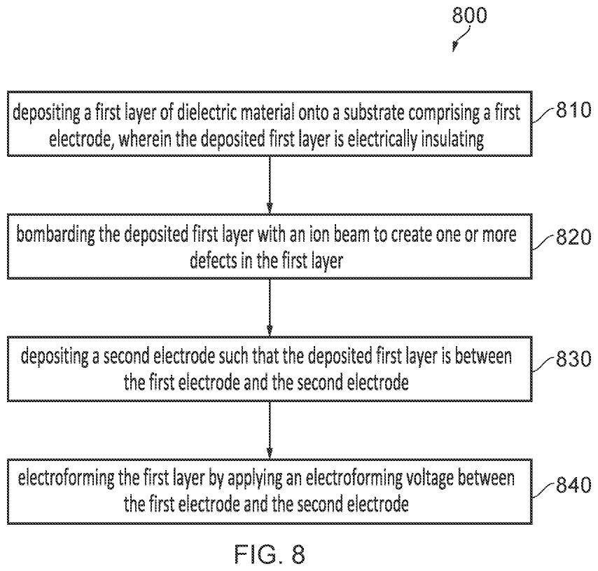

FIG. 8 shows a flowchart outlining a method 800 for manufacturing a memory resistor device. The method includes a step 810 of depositing a first layer of dielectric material onto a substrate comprising a first electrode, wherein the deposited first layer is electrically insulating. The method continues to step 820 of bombarding the deposited first layer with an ion beam to create one or more defects in the first layer. The method continues to step 830 of depositing a second electrode such that the deposited first layer is between the first electrode and the second electrode. The method may further include step 840 of electroforming the first layer by applying an electroforming voltage between the first electrode and the second electrode.

Accordingly, there has been described methods for manufacturing memory resistor devices and memory resistor devices manufactured according to such methods. A method includes depositing a first layer of dielectric material onto a substrate comprising a first electrode; bombarding the deposited first layer with an ion beam to create one or more defects in the first layer; depositing a second electrode such that the deposited first layer is between the first electrode and the second electrode; electroforming the first layer by applying an electroforming voltage between the first electrode and the second electrode.

1. A method for manufacturing a memory resistor device, the method comprising:
depositing a first layer of dielectric material onto a substrate comprising a first electrode, wherein the deposited first layer is electrically insulating;
bombarding the deposited first layer with an ion beam to create one or more defects in the deposited first layer; and
depositing a second electrode such that the deposited first layer is between the first electrode and the second electrode.

2. The method of claim 1, further comprising electroforming the first layer by applying an electroforming voltage between the first electrode and the second electrode.

3. The method of claim 1, wherein prior to the bombarding the deposited first layer is electrically inert.

4. The method of claim 1, wherein the electroforming voltage has an absolute value of up to 20V, more preferably up to 15V, more preferably up to 10V, more preferably up to 5V, more preferably up to 3V.

5. The method of claim 1, wherein the one or more defects in the first layer comprise one or more structural defects in the first layer.

6. The method of claim 5, wherein the one or more defects in the first layer comprise one or more oxygen vacancies.

7. The method of claim 1, wherein the first layer is formed of silicon oxide, SiOx.

8. The method of claim 1, wherein the ion beam comprises ions of a noble gas.

9. The method of claim 8, wherein the ion beam comprises argon ions.

10. The method of claim 1, wherein the bombarding comprises:
providing a masking material on a portion of a surface of the first layer to be bombarded to control a location of the one or more defects in the first layer.

11. The method of claim 10, wherein the masking material is arranged to prevent ions of the ion beam from impacting the first layer, and wherein the masking material comprises one or more cavities permitting ions of the ion beam to pass therethrough.

12. The method of claim 1, wherein the bombarding comprises: controlling an energy of the ion beam to adjust a distance between the one or more defects and the substrate and/or a surface of the first layer to be bombarded.

13. The method according to claim 12, wherein the energy of the ion beam is configurable to a first energy to cause the one or more defects to be closer to the substrate than to the surface of the first layer to be bombarded.

14. The method according to claim 12, wherein the energy of the ion beam is configurable to a second energy to cause the one or more defects to be closer to the surface of the first layer to be bombarded than to the substrate.

15. The method of claim 1, wherein the bombarding comprises:
providing a charge dissipation layer on a portion of a surface of the first layer to be bombarded, wherein the charge dissipation layer is electrically grounded and comprises one or more cavities to allow ions of the ion beam to pass therethrough.

16. The method of claim 15, wherein the charge dissipation layer comprises molybdenum.

17. The method of claim 1, comprising depositing the first layer using atomic layer deposition, ALD.

18. A memory resistor device comprising:
first layer of dielectric material deposited onto a substrate comprising a first electrode, wherein the first layer is electrically insulating, and wherein the first layer includes one or more defects created by bombarding the deposited first layer with an ion beam; and
a second electrode deposited such that the deposited first layer is between the first electrode and the second electrode.

19. The memory resistor device of claim 18, wherein the first layer includes one or conductive filaments which extend at least partially between the first electrode and the second electrode.

20. A memory resistor device manufactured according to the method of claim 1.
